(19) United States
(12) Patent Application Publication
(10) Pub. No.: US 2011/0272000 A1
(43) Pub. Date: Nov. 10, 2011

(54) LINEAR LOW CONCENTRATION PHOTOVOLTAIC GENERATOR

(75) Inventors: Claude OIKNINE, Shoam (IL); Zalman Schwartzman, Rehovot (IL)

(73) Assignees: THERMOGUIDE LTD., Rehovot (IL); GLOBAL ENGINEERING LTD., Shoam (IL)

(21) Appl. No.: 12/774,943

(22) Filed: May 6, 2010

(51) Int. Cl. H01L 31/052

(52) U.S. Cl. 136/246

(57) ABSTRACT

A solar electricity generator including at least one cylindrical solar radiation concentrating and electrical power generating element extending along a longitudinal axis and including a sealed cylindrical tube extending along the longitudinal axis and a multiplicity of photovoltaic cells arranged in a plane and located within the sealed cylindrical tube, and at least one solar tracker operative to rotate each of the at least one cylindrical solar radiation concentrating and electrical power generating element about its the longitudinal axis.

### SUMMARY OF THE INVENTION

The present invention seeks to provide a photovoltaic power generator.

There is thus provided in accordance with a preferred embodiment of the present invention a solar electricity generator including at least one cylindrical solar radiation concentrating and electrical power generating element extending along a longitudinal axis and including a sealed cylindrical tube extending along the longitudinal axis and a multiplicity of photovoltaic cells arranged in a plane and located within the sealed cylindrical tube, and at least one solar tracker operative to rotate each of the at least one cylindrical solar radiation concentrating and electrical power generating element about the longitudinal axis.

Preferably, the at least one solar tracker includes a rotational motor shaft and a motor gear wheel mounted on the rotational motor shaft, the motor gear wheel being operatively meshed with an array of at least one cog wheel, each of the at least one cog wheel formed on one of the at least one cylindrical solar radiation concentrating and power generating element, the cog wheels being interconnected via an array of at least one secondary cog wheel, the at least one solar tracker thereby being operative to axially rotate the at least one cylindrical solar radiation concentrating and power generating element.

Alternatively, the at least one solar tracker includes a rotational motor shaft and a rotating arm extending radially outward from the rotational motor shaft, the rotating arm inducing longitudinal motion of a longitudinal shaft pivotally connected thereto, the longitudinal shaft being pivotally connected to the at least one cylindrical solar radiation concentrating and power generating element and thereby being operative to axially rotate the at least one cylindrical solar radiation concentrating and power generating element.

Alternatively, the at least one solar tracker is integrally formed with each of the at least one cylindrical solar radiation concentrating and electrical power generating element.

In accordance with a preferred embodiment of the present invention, the sealed cylindrical tube is circular. Additionally, the sealed cylindrical tube includes at least one optical focusing element disposed therewithin, the at least one optical focusing element being disposed opposite the multiplicity of photovoltaic cells, thereby focusing solar radiation upon the multiplicity of photovoltaic cells. Preferably, at least one of the at least one optical focusing element is formed as a Fresnel lens. Additionally or alternatively, the at least one optical focusing element within the sealed cylindrical tube is integrally formed therewith.

Preferably, the sealed cylindrical tube includes an inert gas disposed therewithin. Additionally or alternatively, the interior of the sealed cylindrical tube is pressurized to a degree which is greater than that of the exterior of the sealed cylindrical tube.

In accordance with a preferred embodiment of the present invention, at least two of the at least one cylindrical solar radiation concentrating and power generating element are arranged in a serial electricity conducting circuit. Additionally or alternatively, at least two of the at least one cylindrical solar radiation concentrating and power generating element are arranged in a parallel electricity conducting circuit.

Preferably, the multiplicity of photovoltaic cells is arranged in a serial electricity conducting circuit. Additionally, a protective diode is connected in parallel to each of the multiplicity of photovoltaic cells.

Alternatively, the multiplicity of photovoltaic cells is arranged in a parallel electricity conducting circuit. Additionally, at least one protective diode is connected in parallel to the multiplicity of photovoltaic cells.

Alternatively, the multiplicity of photovoltaic cells is arranged in a multiplicity of sub-circuits of photovoltaic cells, the multiplicity of sub-circuits of photovoltaic cells is arranged in a serial electricity conducting circuit and the photovoltaic cells of each of the multiplicity of sub-circuits of photovoltaic cells are arranged in a parallel electricity conducting circuit. Additionally, a protective diode is connected in parallel to each of the multiplicity of sub-circuits of photovoltaic cells.

In accordance with a preferred embodiment of the present invention, the at least one cylindrical solar radiation concentrating and power generating element also includes an elongate heat absorbing element longitudinally disposed within the sealed cylindrical tube, the heat absorbing element being arranged to radially dissipate absorbed heat outwardly of the sealed cylindrical tube, thereby cooling the interior of the sealed cylindrical tube. Additionally, the elongate heat absorbing element is shaped as an elongate optical reflecting element thereby being operative to focus solar radiation upon the multiplicity of photovoltaic cells.

Alternatively, the at least one cylindrical solar radiation concentrating and power generating element also includes an elongate heat absorbing element longitudinally disposed within the sealed cylindrical tube, the heat absorbing element being arranged to longitudinally dissipate absorbed heat outwardly of the sealed cylindrical tube, thereby cooling the interior of the sealed cylindrical tube. Additionally, the elongate heat absorbing element is shaped as an elongate optical reflecting element thereby being operative to focus solar radiation upon the multiplicity of photovoltaic cells.

Alternatively, the at least one cylindrical solar radiation concentrating and power generating element also includes an elongate heat absorbing element longitudinally disposed within the sealed cylindrical tube, the heat absorbing element being arranged to radially dissipate absorbed heat outwardly of the sealed cylindrical tube and to longitudinally dissipate heat outwardly of the sealed cylindrical tube, thereby cooling the interior of the sealed cylindrical tube. Additionally, the elongate heat absorbing element is shaped as an elongate optical reflecting element thereby being operative to focus solar radiation upon the multiplicity of photovoltaic cells.

### BRIEF DESCRIPTION OF THE DRAWINGS

The present invention will be understood and appreciated more fully from the following detailed description, taken in conjunction with the drawings in which:

FIG. 1 is a simplified pictorial illustration of a photovoltaic solar generator constructed and operative with a preferred embodiment of the invention;

FIG. 2 is a simplified pictorial view of a cylindrical solar radiation concentrating and power generating element forming part of the photovoltaic solar generator of FIG. 1;

FIGS. 3A and 3B are simplified respective sectional illustrations of the cylindrical solar radiation concentrating and power generating element of FIG. 2, taken along mutually perpendicular section lines IIIA-IIIA and IIIB-IIIB in FIG. 2; and

FIG. 4 is a simplified side view of an alternative embodiment of a rotational transmission mechanism forming part of the photovoltaic solar generator of FIG. 1.

### DETAILED DESCRIPTION OF A PREFERRED EMBODIMENT

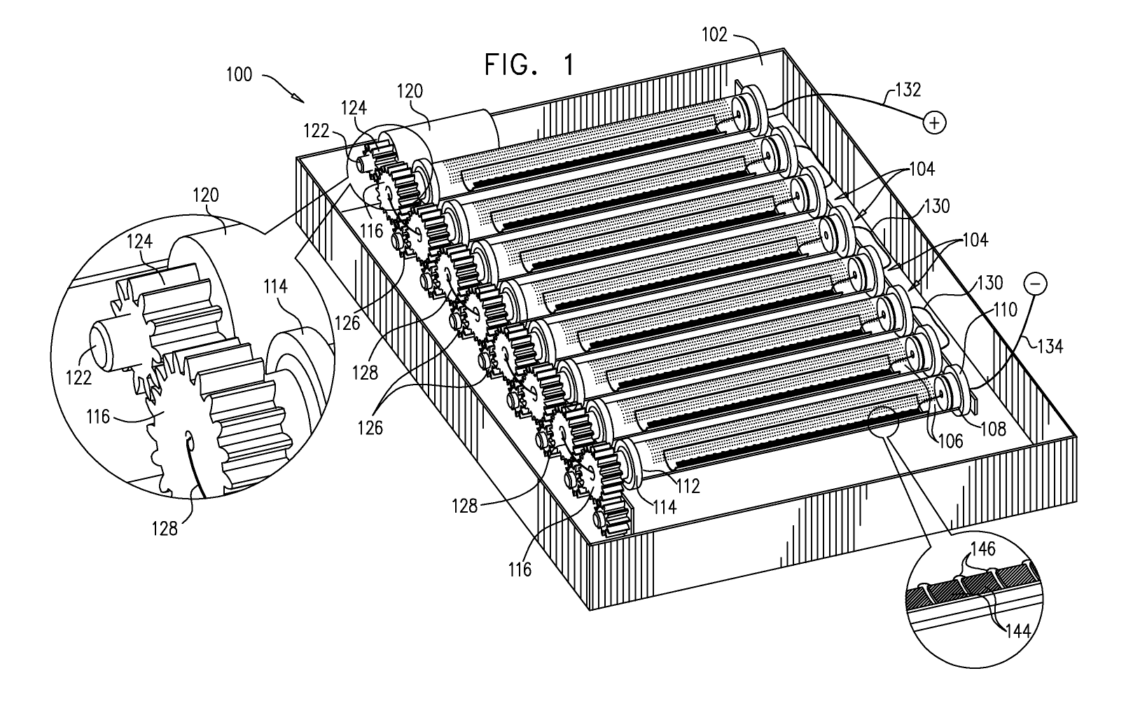

Reference is now made to FIG. 1, which is a simplified pictorial illustration of a photovoltaic solar generator constructed and operative with a preferred embodiment of the invention;

As seen in FIG. 1, there is provided a low concentration photovoltaic solar generator 100 with a concentration ratio of 3-50, having a generally planar solar collector housing 102 and an array of at least one and preferably multiple cylindrical solar radiation concentrating and power generating elements 104 mounted thereupon, each of elements 104 configured to rotate about a longitudinal axis.

The cylindrical solar radiation concentrating and power generating elements 104 are formed with a generally elongate cylindrical conduit 106 extending from a rearwardly facing end 108 sealed with a rearwardly facing sealing element 110 to a forwardly facing end 112 sealed with a forwardly facing sealing element 114. Preferably, conduit 106 is formed of transparent glass. Preferably, forwardly facing sealing element 114 is formed with a circular gear wheel 116 extending forwardly thereof.

The solar collector housing 102 also includes a solar tracker comprising a servomotor 120 controlled by a servomechanism (not shown), which is formed with a rotational motor shaft 122 and a motor gear wheel 124 mounted thereon or formed integrally therewith. At least one and preferably multiple secondary gear wheels 126 are rotationally mounted upon housing 102. Gear wheel 124 is operatively meshed with gear wheel 116 of a first of power generating elements 104 which in turn is operatively meshed with a first of secondary gear wheels 126. As seen clearly in FIG. 1, motor gear wheel 124, gear wheel 116 of each of power generating elements 104 and secondary gear wheels 126 form a rotational transmission mechanism which is operative to rotate the power generating elements 104.

In an alternative embodiment of the present invention, each of the cylindrical solar radiation concentrating and power generating elements 104 may include a cylindrical solar radiation concentrating and power generating element solar tracker including a cylindrical solar radiation concentrating and power generating element servomotor controlled by a cylindrical solar radiation concentrating and power generating element servomechanism, both of which being integrally formed within forwardly facing sealing element 114.

As seen in FIG. 1, power generating elements 104 are serially connected to allow flow of electricity therebetween, whereby a plurality of forward electricity conducting elements 128 sealingly extending through forwardly facing sealing elements 114 of power generating elements 104 forwardly connect each pair of adjacent power generating elements 104, and a plurality of rearward electricity conducting elements 130 sealingly extending through rearwardly facing sealing elements 110 of power generating elements 104 rearwardly connect each alternate pair of adjacent power generating elements 104.

As clearly seen in FIG. 1, a positive electric terminal 132 sealingly extends through rearwardly facing end 108 of a first of power generating elements 104, and a negative electric terminal 134 sealingly extends through rearwardly facing end 108 of a last of power generating elements 104.

It is appreciated that the power generating elements 104 in the state shown in FIG. 1 form an electric circuit between positive electric terminal 132 and negative electric terminal 134, allowing electricity generated by power generating elements 104 to flow between terminals 132 and 134.

In an alternative embodiment of the present invention, power generating elements 104 may be electrically connected in parallel between positive electric terminal 132 and negative electric terminal 134.

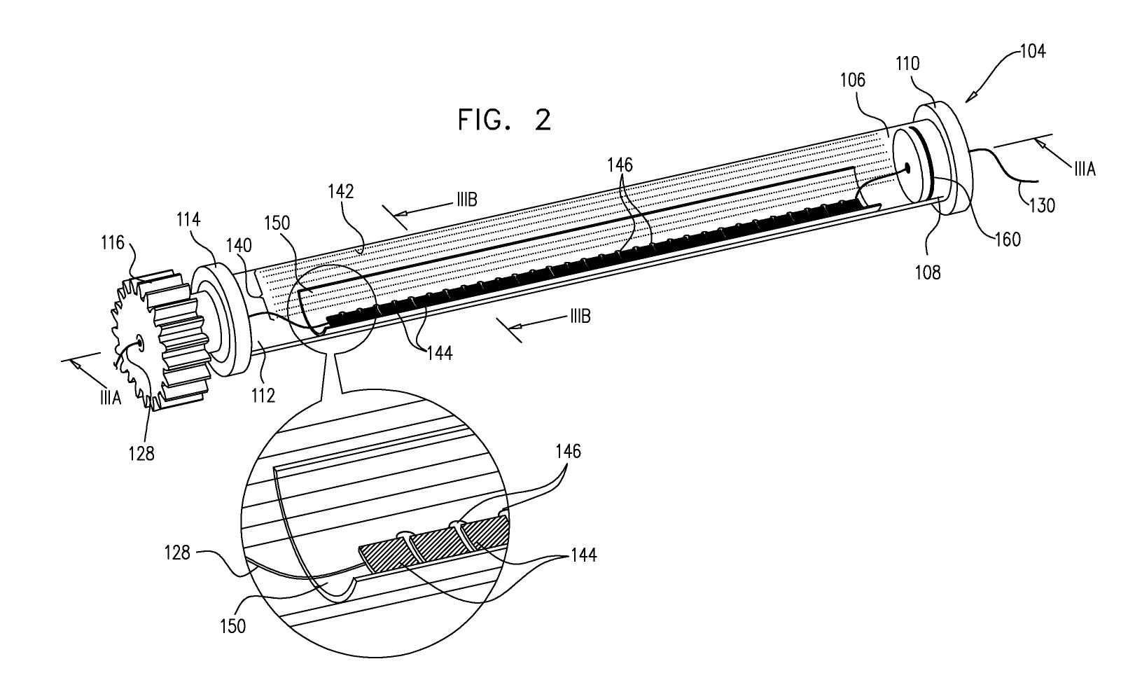

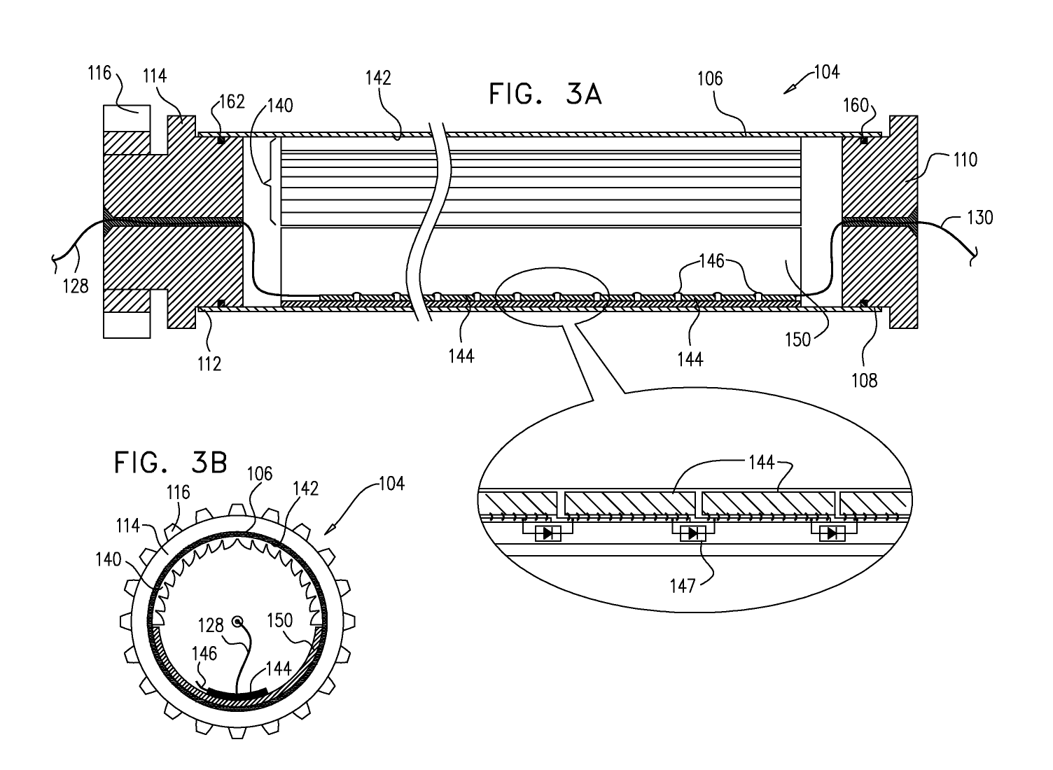

Reference is now made to FIG. 2, which is a simplified pictorial view of a cylindrical solar radiation concentrating and power generating element 104 forming part of the photovoltaic solar generator 100 of FIG. 1, and to FIGS. 3A and 3B, which are simplified respective sectional illustrations of the cylindrical solar radiation concentrating and power generating element 104 of FIG. 2, taken along mutually perpendicular section lines IIIA-IIIA and IIIB-IIIB in FIG. 2.

As noted hereinabove with reference to FIG. 1, the power generating element 104 is formed with a generally elongate cylindrical conduit 106 extending from a rearwardly facing end 108 sealed with a rearwardly facing sealing element 110 to a forwardly facing end 112 sealed with a forwardly facing sealing element 114. Forwardly facing sealing element 114 is formed with a circular gear wheel 116 extending forwardly thereof. Forward electricity conducting element 128 sealingly extends through forwardly facing sealing element 114 and rearward electricity conducting element 130 sealingly extends through rearwardly facing sealing element 110.

As seen in FIGS. 2-3B, element 104 also includes an elongate transparent optical focusing element 140 preferably formed as a linear Fresnel lens, which is longitudinally disposed along an inner surface 142 of conduit 106 opposite an array of at least one and preferably multiple photovoltaic cells 144, thereby focusing solar radiation thereupon. Alternatively, transparent optical focusing element 140 may be integrally formed as part of conduit 106.

As seen in FIGS. 2 and 3A, photovoltaic cells 144 are serially connected by a plurality of electricity conducting elements 146, thereby enabling electricity to flow between forward electricity conducting element 128 and rearward electricity conducting element 130. Connected in parallel to each of the conducting elements 146 is a protective diode 147, which prevents electric current from flowing in a reverse direction when some of the photovoltaic cells 144 are shaded.

In an alternative embodiment of the present invention, photovoltaic cells 144 and at least one protective diode 147 may be connected in parallel between forward electricity conducting element 128 and rearward electricity conducting element 130.

In yet another alternative embodiment of the present invention, photovoltaic cells 144 may be arranged in sub-circuits of photovoltaic cells, whereby the sub-circuits of photovoltaic cells are connected in series between forward electricity conducting element 128 and rearward electricity conducting element 130, and whereby the photovoltaic cells 144 of each individual sub-circuit are connected in parallel between two terminals of the individual sub-circuit. A protective diode 147 is connected in parallel to each of the sub-circuits of photovoltaic cells.

Photovoltaic cells 144 are preferably mounted upon an elongate heat conducting element 150 which is longitudinally disposed along the inner surface 142 of conduit 106 opposite elongate transparent optical focusing element 140. In some embodiments of the present invention, heat conducting element 150 may be shaped as an elongate optical reflecting element, thereby being operative to focus solar radiation upon photovoltaic cells 144.

Heat conducting element 150 is operative to absorb and radially outwardly dissipate heat from the interior of conduit 106 to the exterior thereof. In an alternative embodiment of the present invention, heat conducting element 150 may be arranged to longitudinally dissipate heat absorbed from the interior of conduit 106 to the exterior thereof via rearwardly facing sealing element 110 and forwardly facing sealing element 114.

As seen in FIGS. 2 and 3A, rearwardly facing sealing element 110 and forwardly facing sealing element 114 are tightly and sealingly disposed within a first sealing ring 160 and a second sealing ring 162 respectively, thereby sealing the interior of conduit 106 from the exterior thereof. Sealing rings 160 and 162 are sealingly and circumferentially disposed within conduit 106 and are preferably formed of an elastomeric material such as silicone. As noted hereinabove, conducting element 128 sealingly extends through forwardly facing sealing element 114 and conducting element 130 sealingly extends through sealing element 110.

It is a particular feature of this embodiment of the present invention that the power generating elements 104 in the state shown in FIGS. 2 and 3A are capable of maintaining a pressurized seal for pressurized gas in conduit 106, thereby creating a protective environment for electronic components disposed therewithin such as photovoltaic cells 144.

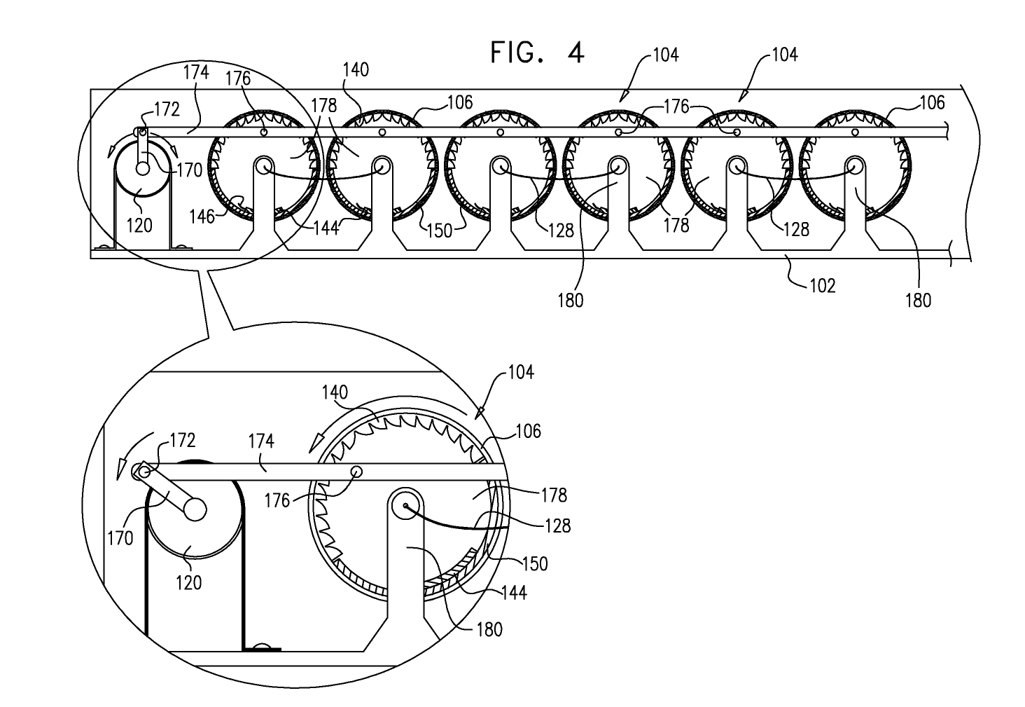

Reference is now made to FIG. 4, which is a simplified side view of an alternative embodiment of a rotational transmission mechanism forming part of the photovoltaic solar generator of FIG. 1. As seen in FIG. 4, a rotating arm 170 extends radially outward from servomotor 120, and is operative to rotate up to ninety degrees to either side of an initial vertical position. Rotating arm 170 is formed with a rotational mounting joint 172 which is pivotally mounted on a first end of an elongate longitudinal shaft 174. Shaft 174 is mounted on a plurality of pivots 176, each of which being formed on a forwardly facing surface 178 of the forwardly facing sealing element 114 of each of power generating elements 104. Elements 104 are rotationally disposed within a plurality of vertical housing elements 180 vertically extending from solar collector housing 102.

As seen clearly in FIG. 4, rotating arm 170 and elongate longitudinal shaft 174 form a rotational transmission mechanism which is operative to rotate the power generating elements 104 up to ninety degrees to either side of an initial vertical position.

It will be appreciated by persons skilled in the art that the present invention is not limited by what has been particularly shown and described hereinabove. Rather the scope of the present invention includes both combinations and subcombinations of various features described hereinabove as well as variations and modifications thereof which are not in the prior art.

1. A solar electricity generator comprising:
at least one cylindrical solar radiation concentrating and electrical power generating element extending along a longitudinal axis and including:
a sealed cylindrical tube extending along said longitudinal axis; and
a multiplicity of photovoltaic cells arranged in a plane and located within said sealed cylindrical tube; and
at least one solar tracker operative to rotate each of said at least one cylindrical solar radiation concentrating and electrical power generating element about said longitudinal axis.

2. A solar electricity generator according to claim 1 and wherein said at least one solar tracker comprises a rotational motor shaft and a motor gear wheel mounted on said rotational motor shaft, said motor gear wheel being operatively meshed with an array of at least one cog wheel, each of said at least one cog wheel formed on one of said at least one cylindrical solar radiation concentrating and power generating element, said cog wheels being interconnected via an array of at least one secondary cog wheel, said at least one solar tracker thereby being operative to axially rotate said at least one cylindrical solar radiation concentrating and power generating element.

3. A solar electricity generator according to claim 1 and wherein said at least one solar tracker comprises a rotational motor shaft and a rotating arm extending radially outward from said rotational motor shaft, said rotating arm inducing longitudinal motion of a longitudinal shaft pivotally connected thereto, said longitudinal shaft being pivotally connected to said at least one cylindrical solar radiation concentrating and power generating element and thereby being operative to axially rotate said at least one cylindrical solar radiation concentrating and power generating element.

4. A solar electricity generator according to claim 1 and wherein said at least one solar tracker is integrally formed with each of said at least one cylindrical solar radiation concentrating and electrical power generating element.

5. A solar electricity generator according to claim 1 and wherein said sealed cylindrical tube is circular.

6. A solar electricity generator according to claim 1 and wherein said sealed cylindrical tube includes at least one optical focusing element disposed therewithin, said at least one optical focusing element being disposed opposite said multiplicity of photovoltaic cells, thereby focusing solar radiation upon said multiplicity of photovoltaic cells.

7. A solar electricity generator according to claim 6 and wherein at least one of said at least one optical focusing element is formed as a Fresnel lens.

8. A solar electricity generator according to claim 6 and wherein said at least one optical focusing element within said sealed cylindrical tube is integrally formed therewith.

9. A solar electricity generator according to claim 1 and wherein said sealed cylindrical tube includes an inert gas disposed therewithin.

10. A solar electricity generator according to claim 1 and wherein the interior of said sealed cylindrical tube is pressurized to a degree which is greater than that of the exterior of said sealed cylindrical tube.

11. A solar electricity generator according to claim 1 and wherein at least two of said at least one cylindrical solar radiation concentrating and power generating element are arranged in a serial electricity conducting circuit.

12. A solar electricity generator according to claim 1 and wherein at least two of said at least one cylindrical solar radiation concentrating and power generating element are arranged in a parallel electricity conducting circuit.

13. A solar electricity generator according to claim 1 and wherein said multiplicity of photovoltaic cells is arranged in a serial electricity conducting circuit.

14. A solar electricity generator according to claim 13 and wherein a protective diode is connected in parallel to each of said multiplicity of photovoltaic cells.

15. A solar electricity generator according to claim 1 and wherein said multiplicity of photovoltaic cells is arranged in a parallel electricity conducting circuit.

16. A solar electricity generator according to claim 15 and wherein at least one protective diode is connected in parallel to said multiplicity of photovoltaic cells.

17. A solar electricity generator according to claim 1 and wherein:
said multiplicity of photovoltaic cells is arranged in a multiplicity of sub-circuits of photovoltaic cells;
said multiplicity of sub-circuits of photovoltaic cells is arranged in a serial electricity conducting circuit; and
said photovoltaic cells of each of said multiplicity of sub-circuits of photovoltaic cells are arranged in a parallel electricity conducting circuit.

18. A solar electricity generator according to claim 17 and wherein a protective diode is connected in parallel to each of said multiplicity of sub-circuits of photovoltaic cells.

19. A solar electricity generator according to claim 1 and wherein said at least one cylindrical solar radiation concentrating and power generating element also comprises an elongate heat absorbing element longitudinally disposed within said sealed cylindrical tube, said heat absorbing element being arranged to radially dissipate absorbed heat outwardly of said sealed cylindrical tube, thereby cooling the interior of said sealed cylindrical tube.

20. A solar electricity generator according to claim 19 and wherein said elongate heat absorbing element is shaped as an elongate optical reflecting element thereby being operative to focus solar radiation upon said multiplicity of photovoltaic cells.

21. A solar electricity generator according to claim 1 and wherein said at least one cylindrical solar radiation concentrating and power generating element also comprises an elongate heat absorbing element longitudinally disposed within said sealed cylindrical tube, said heat absorbing element being arranged to longitudinally dissipate absorbed heat outwardly of said sealed cylindrical tube, thereby cooling the interior of said sealed cylindrical tube.

22. A solar electricity generator according to claim 21 and wherein said elongate heat absorbing element is shaped as an elongate optical reflecting element thereby being operative to focus solar radiation upon said multiplicity of photovoltaic cells.

23. A solar electricity generator according to claim 1 and wherein said at least one cylindrical solar radiation concentrating and power generating element also comprises an elongate heat absorbing element longitudinally disposed within said sealed cylindrical tube, said heat absorbing element being arranged to radially dissipate absorbed heat outwardly of said sealed cylindrical tube and to longitudinally dissipate heat outwardly of said sealed cylindrical tube, thereby cooling the interior of said sealed cylindrical tube.

24. A solar electricity generator according to claim 23 and wherein said elongate heat absorbing element is shaped as an elongate optical reflecting element thereby being operative to focus solar radiation upon said multiplicity of photovoltaic cells.
